(19) United States
(12) Patent Application Publication
(10) Pub. No.: US 2021/0020729 A1
(43) Pub. Date: Jan. 21, 2021

(54) DISPLAY DEVICE AND DEFECTIVE PIXEL REPAIRING METHOD THEREOF

(71) Applicant: SHARP KABUSHIKI KAISHA, Sakai City, Osaka (JP)

(72) Inventor: HIDEHITO KITAKADO, Sakai City, Osaka (JP)

(73) Assignee: SHARP KABUSHIKI KAISHA, Sakai City, Osaka (JP)

(21) Appl. No.: 16/981,999

(22) PCT Filed: Mar. 29, 2018
(86) PCT No.: PCT/JP2018/013368

§ 371 Date: Sep. 17, 2020

(51) Int. Cl. H01L 27/32; G09G 3/3266; G09G 3/20; G09G 3/3291

(52) U.S. Cl. CPC H01L 27/3276; G09G 3/3266; G09G 3/2092; G09G 2300/0452; G09G 3/3291; G09G 2330/10; G09G 2330/08; G09G 3/2003

(57) ABSTRACT

A display device has a plurality of pixels each including a drive transistor and an electro-optical element. A defective pixel repairing method of the display device includes electrically connecting an anode electrode of the electro-optical element in a defective pixel with the anode electrode of the electro-optical element in an adjacent normal pixel of same color, by irradiating a laser to an overlapping portion of two wirings formed in different wiring layers and having the overlapping portion via an insulating film in a plan view, to short-circuit the two wirings, and electrically disconnecting, in the defective pixel, the drive transistor from the electro-optical element. With this, the defective pixel can be repaired easily.

### TECHNICAL FIELD

The present invention relates to a display device, especially to a display device having a pixel including an electro-optical element and a defective pixel repairing method thereof.

### BACKGROUND ART

In recent years, an organic electro luminescence (hereinafter referred to as EL) display device having a pixel including an organic EL element is put into practical use. The pixel of the organic EL display device includes the organic EL element and a drive transistor. The organic EL element is one kind of an electro-optical element that emits light with luminance in accordance with an amount of a current flowing therethrough. The drive transistor is provided in series with the organic EL element and controls the amount of the current flowing through the organic EL element. A thin film transistor (hereinafter referred to as TFT) is used as a transistor in the pixel.

In a manufacturing process of the organic EL display device, a defect occurs in the pixel. Luminance of a defective pixel is different from that of a normal pixel. Therefore, in a test process of the organic EL display device, there is performed processing for detecting the defective pixel based on an image displayed when a test pattern is provided, for example. Furthermore, in order to make the defective pixel inconspicuous, there may be performed processing for fixing a color of the defective pixel to black (hereinafter referred to as dot blacking). The dot blacking is performed, for example, by a method of separating a light emitting area of the organic EL element from a pixel electrode or a method of disconnecting the light emitting area of the organic EL element from the drive transistor.

In a small-sized organic EL display device, since the number of pixels is small, the number of defective pixels is also small. Thus, the organic EL display device can be shipped as a good product by making the defective pixels inconspicuous by the dot blacking. On the other hand, in a medium-sized or large-sized organic EL display device, since the number of pixels is large, the number of defective pixels is also large. Thus, there may be a case in which the organic EL display device cannot be shipped as a good product even if the defective pixels are made inconspicuous by the dot blacking. Therefore, it is preferable that the defective pixels are repaired in the medium-sized or large-sized organic EL display device.

Various methods are conventionally known for defective pixel repairing. Patent Document 1 describes a manufacturing method of a display device in which when a failure of a switching transistor is detected before forming a display element, a current path from a power supply line to the switching transistor with the failure is disconnected, a passivation film is formed on a substrate so as to cover a pixel, and a second electrode of the disconnected switching transistor and a second electrode of a drive transistor in an adjacent pixel are connected using the passivation film. Patent Document 2 describes a correcting method of an image display device in which when forming a drive circuit layer, openings are formed on a surface of a gate terminal of a drive transistor in a defective pixel and a surface of the gate terminal of the drive transistor in a normal pixel, and a jumper line directly connecting the gate terminals of the two drive transistors via the two openings is formed.

### PRIOR ART DOCUMENTS

### Patent Documents

[Patent Document 1] Japanese Laid-Open Patent Publication No. 2008-262013

[Patent Document 2] Japanese Laid-Open Patent Publication No. 2010-249883

### SUMMARY OF THE INVENTION

### Problems to be Solved by the Invention

However, the conventional defective pixel repairing methods have a problem that it is difficult to perform or high-cost because in forming the pixel, the defective pixel is detected and the passivation film or the jumper line is formed.

Therefore, providing a defective pixel repairing method of a display device that can be performed easily is taken as a problem.

### Means for Solving the Problems

The above problem can be solved, for example, by a defective pixel repairing method of a display device having a plurality of pixels each including a drive transistor and an electro-optical element, the method including electrically connecting an anode electrode of the electro-optical element in a defective pixel with the anode electrode of the electro-optical element in an adjacent normal pixel of same color, by irradiating a laser to an overlapping portion of two wirings formed in different wiring layers and having the overlapping portion via an insulating film in a plan view, to short-circuit the two wirings, and electrically disconnecting, in the defective pixel, the drive transistor from the electro-optical element.

### Effects of the Invention

According to the above-described defective pixel repairing method, by electrically connecting the anode electrode of the electro-optical element in the defective pixel with the anode electrode of the electro-optical element in the normal pixel and electrically disconnecting, in the defective pixel, the drive transistor from the electro-optical element, an amount of a current flowing through the electro-optical element in the defective pixel becomes almost the same as an amount of a current flowing through the electro-optical element in the normal pixel that shares the drive transistor, and luminance of the defective pixel becomes almost the same as luminance of the normal pixel that shares the drive transistor. Furthermore, the luminance of the defective pixel becomes as described above only by irradiating the laser to the overlapping portion of the two wirings and electrically disconnecting the drive transistor from the electro-optical element. Therefore, the defective pixel can be repaired easily.

### BRIEF DESCRIPTION OF THE DRAWINGS

FIG. 1 is a block diagram showing a configuration of an organic EL display device according to a first embodiment.

FIG. 2 is a circuit diagram of pixels of the organic EL display device shown in FIG. 1.

FIG. 3 is a timing chart of the organic EL display device shown in FIG. 1.

FIG. 4 is a diagram showing end portions of connection wirings in the pixels shown in FIG. 2.

FIG. 5 is a diagram for explaining a defective pixel repairing method of the organic EL display device shown in FIG. 1.

FIG. 6 is a circuit diagram of the pixels of the organic EL display device shown in FIG. 1 after repairing.

FIG. 7 is a layout diagram of a display section of an organic EL display device according to a first example of a second embodiment.

FIG. 8 is a layout diagram of a display section of an organic EL display device according to a second example of the second embodiment.

FIG. 9 is a layout diagram of a display section of an organic EL display device according to a third example of the second embodiment.

FIG. 10 is a layout diagram of a display section of an organic EL display device according to a first example of a third embodiment.

FIG. 11 is a layout diagram of a display section of an organic EL display device according to a second example of the third embodiment.

### MODES FOR CARRYING OUT THE INVENTION

### First Embodiment

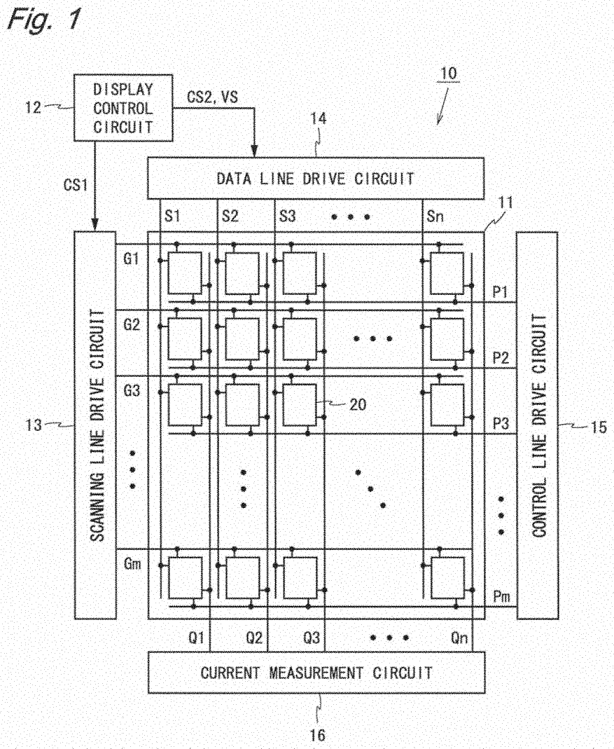

FIG. 1 is a block diagram showing a configuration of an organic EL display device according to a first embodiment. An organic EL display device 10 shown in FIG. 1 includes a display section 11, a display control circuit 12, a scanning line drive circuit 13, a data line drive circuit 14, a control line drive circuit 15, and a current measurement circuit 16. In the following, it is assumed that m is an even number, n is an integer not smaller than two, i is an integer not smaller than one and not larger than m, and j is an integer not smaller than one and not larger than n. Furthermore, a horizontal direction of the drawings is referred to as a row direction, and a vertical direction of the drawings is referred to as a column direction.

The display section 11 includes m scanning lines G1 to Gm, n data lines S1 to Sn, m control lines P1 to Pm, n monitor lines Q1 to Qn, and (m×n) pixels 20. The scanning lines G1 to Gm and the control lines P1 to Pm extend in the row direction and are arranged in parallel with each other. The data lines S1 to Sn and the monitor lines Q1 to Qn extend in the column direction and are arranged in parallel to each other so as to intersect with the scanning lines G1 to Gm perpendicularly. The scanning lines G1 to Gm and the data lines S1 to Sn intersect at (m×n) points. The (m×n) pixels 20 are arranged two-dimensionally corresponding to intersections of the scanning lines G1 to Gm and the data lines S1 to Sn. A high-level power supply voltage ELVDD and a low-level power supply voltage ELVSS are supplied to the pixel 20 using a wiring or an electrode not shown in the drawing.

The display control circuit 12 outputs a control signal CS1 to the scanning line drive circuit 13, and outputs a control signal CS2 and a video signal VS to the data line drive circuit 14. The scanning line drive circuit 13 drives the scanning lines G1 to Gm based on the control signal CS1. More specifically, the scanning line drive circuit 13 selects one scanning line in turn from among the scanning lines G1 to Gm based on the control signal CS1, and applies a high-level voltage to the selected scanning line. With this, n pixels 20 connected to the selected scanning line are selected collectively. The data line drive circuit 14 drives the data lines S1 to Sn based on the control signal CS2 and the video signal VS. More specifically, the data line drive circuit 14 applies n voltages in accordance with the video signal VS (hereinafter referred to as data voltages) to the data lines S1 to Sn based on the control signal CS2. With this, the n data voltages are respectively written to the n pixels connected to the selected scanning line. Luminance of the pixel 20 changes in accordance with the data voltage written to the pixel 20.

The control line drive circuit 15 drives the control lines P1 to Pm. More specifically, the control line drive circuit 15 selects one control line from among the control lines P1 to Pm in a non-display period such as a retrace period and applies the high-level voltage to the selected control line. With this, n pixels 20 connected to the selected control line are selected collectively. The current measurement circuit 16 measures n currents flowing through the selected n pixels 20 and the monitor lines Q1 to Qn. The measured currents are used to correct the video signal VS, for example. Note that a signal supply circuit may be provided in place of the current measurement circuit 16 and an initialization signal or the like may be supplied to the pixels 20 using the monitor lines Q1 to Qn as signal supply lines.

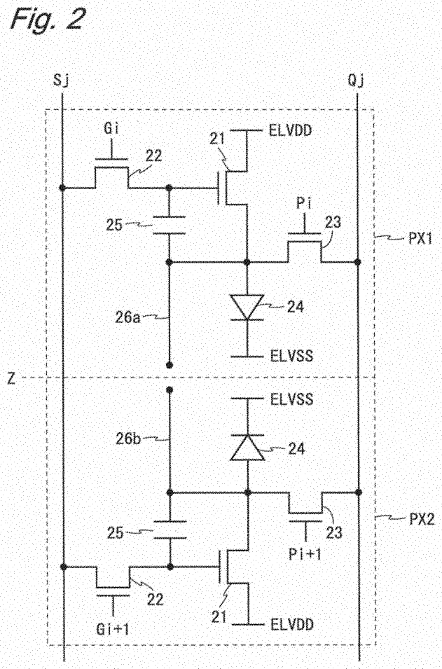

FIG. 2 is a circuit diagram of the pixel 20. FIG. 2 describes the pixel 20 in an i-th row and a j-th column and the pixel 20 in an (i+1)-th row and the j-th column. In the following, the former is referred to as PX1 and the latter is referred to as PX2. The pixels PX1, PX2 are adjacent in an extending direction of the data lines S1 to Sn. The pixel PX1 includes TFTs 21 to 23, an organic EL element 24, and a capacitor 25. The TFTs 21 to 23 are N-channel type TFTs.

The high-level power supply voltage ELVDD is applied to a drain terminal of the TFT 21. A source terminal of the TFT 21 is connected to an anode electrode of the organic EL element 24 and one conduction terminal (left-side terminal in FIG. 2) of the TFT 23. The low-level power supply voltage ELVSS is applied to a cathode electrode of the organic EL element 24. One conduction terminal (left-side terminal in FIG. 2) of the TFT 22 is connected to a data line Sj, and the other conduction terminal of the TFT 22 is connected to a gate terminal of the TFT 21. A gate terminal of the TFT 22 is connected to a scanning line Gi. The other conduction terminal of the TFT 23 is connected to a monitor line Qj, and a gate terminal of the TFT 23 is connected to a control line Pi. The capacitor 25 is provided between the gate terminal and the source terminal of the TFT 21. The TFT 21 functions as a drive transistor that controls an amount of a current flowing through the organic EL element 24.

The pixel PX2 has a same configuration as the pixel PX1. Elements in the pixel PX2 are connected in a manner similar to those in the pixel PX1. However, in the pixel PX2, the gate terminal of the TFT 22 is connected to a scanning line Gi+1, and the gate terminal of the TFT 23 is connected to a control line Pi+1. The pixel PX2 has a configuration that is almost line-symmetric to that of the pixel PX1 with a boundary line Z between the pixels PX1, PX2 as an axis of symmetry. Note that almost line-symmetry includes perfect line-symmetry.

The organic EL element 24 emits light with a color that is one of red, green, and blue. The pixel 20 functions as one of a red pixel, a green pixel, and a blue pixel in accordance with a light emission color of the organic EL element 24. In the organic EL display device 10, the organic EL elements 24 in the pixels 20 arranged in a same column emit with a same color. Therefore, the color of the pixel PX1 and that of the pixel PX2 are the same. In the organic EL display device 10, the pixel 20 has a configuration that is almost line-symmetric to that of an adjacent pixel of same color.

Note that the TFT included in the pixel 20 may be an amorphous silicon transistor having a channel layer formed of amorphous silicon, a low-temperature polysilicon transistor having a channel layer formed of low-temperature polysilicon, or an oxide semiconductor transistor having a channel layer formed of oxide semiconductor. As the oxide semiconductor, indium gallium zinc oxide (referred to as IGZO) may be used, for example. Furthermore, the TFT included in the pixel 20 may be of top gate type or of bottom gate type.

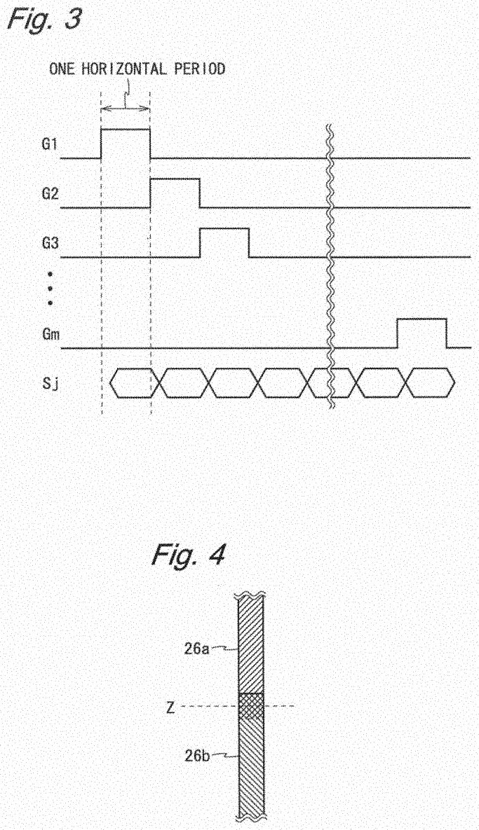

FIG. 3 is a timing chart of the organic EL display device 10. In the organic EL display device 10, m horizontal periods are set in one frame period. In an i-th horizontal period, the scanning line drive circuit 13 applies the high-level voltage to the scanning line Gi, and the data line drive circuit 14 applies the n data voltages to the data lines S1 to Sn, respectively. At this time, in the pixel 20 in the i-th row, the TFT 22 turns on and the data voltage is written to the gate terminal of the TFT 21.

At the end of the i-th horizontal period, the scanning line drive circuit 13 applies a low-level voltage to the scanning line Gi. Therefore, in the pixel 20 in the i-th row, the TFT 22 turns off. Even after the TFT 22 turns off, a gate-source voltage of the TFT 21 is kept at a level at the time of writing by an action of the capacitor 25. A current having an amount corresponding to the gate-source voltage of the TFT 21 flows through the TFT 21 and the organic EL element 24. The organic EL element 24 emits light with luminance in accordance with the gate-source voltage of the TFT 21. Luminance of the pixel 20 (luminance of the organic EL element 24) changes in accordance with the data voltage.

In a similar manner, the data voltage is written to the gate terminal of the TFT 21 in the pixel 20 in other rows. Luminance of the pixel 20 in the other rows also changes in accordance with the data voltage. The organic EL display device 10 displays an image in accordance with the video signal VS by driving the scanning lines G1 to Gm and the data lines S1 to Sn using the scanning line drive circuit 13 and the data line drive circuit 14.

With respect to the organic EL display device 10, a detecting step of a defective pixel and a repairing step thereof are performed after forming the display section 11 and before shipping. In the defective pixel detecting step, the defective pixel is detected by a predetermined method. The defective pixel is detected by analyzing an image displayed when a test pattern is provided, for example. As described below, in the defective pixel repairing step, the anode electrode of the organic EL element 24 in the defective pixel and the anode electrode of the organic EL element 24 in a normal pixel are electrically connected using a connection wiring provided in advance, and in the defective pixel, the TFT 21 (drive transistor) is electrically disconnected from the organic EL element 24.

The pixel 20 includes a connection wiring. In the following, the connection wirings in the pixels PX1, PX2 are referred to as wirings 26a, 26b, respectively (see FIG. 2). The wirings 26a, 26b are formed in different wiring layers. One end (upper end in FIG. 2) of the wiring 26a is connected to the anode electrode of the organic EL element 24 in the pixel PX1. One end (lower end in FIG. 2) of the wiring 26b is connected to the anode electrode of the organic EL element 24 in the pixel PX2. Before performing the defective pixel repairing step, the other ends of the wirings 26a, 26b are not connected to any other elements. As with other elements, the wirings 26a, 26b are formed so as to be almost line-symmetric with the boundary line Z as the axis of symmetry.

FIG. 4 is a diagram showing end portions of the wirings 26a, 26b. FIG. 4 describes the wirings 26a, 26b near the boundary line Z. The wiring 26a extends in a downward direction in the drawing from a node connected to the anode electrode of the organic EL element 24 in the pixel PX1 and reaches a vicinity of the boundary line Z. The wiring 26b extends in an upward direction in the drawing from a node connected to the anode electrode of the organic EL element 24 in the pixel PX2 and reaches the vicinity of the boundary line Z. The wirings 26a, 26b are formed so that the other ends overlap via an insulating film (not shown) in a plan view. A cross hatch portion shown in FIG. 4 represents an overlapping portion of the wirings 26a, 26b. Note that an organic insulating film is used as the insulating film, for example.

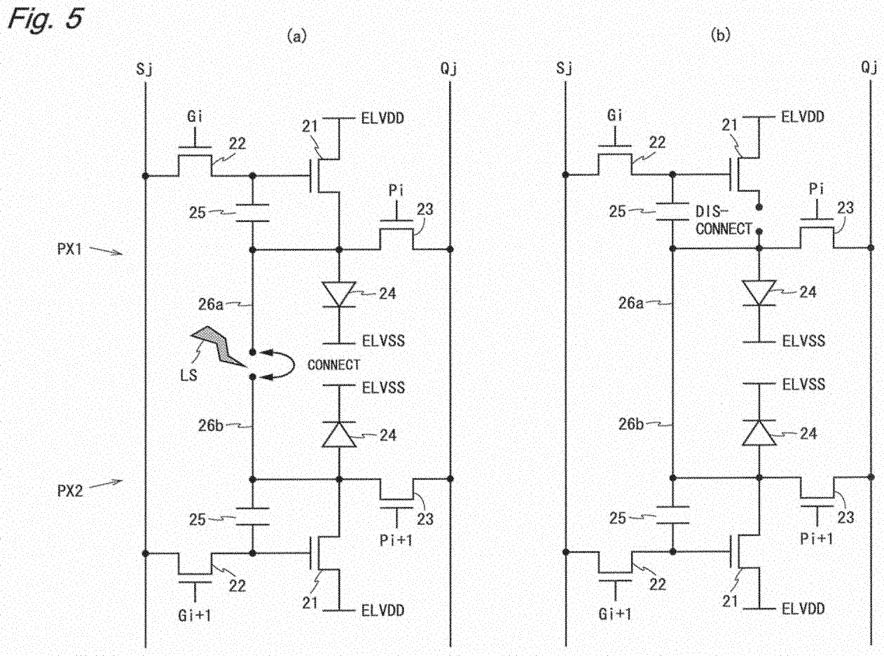

FIG. 5 is a diagram for explaining a defective pixel repairing method of the organic EL display device 10. Here, it is assumed that the pixel PX1 is a defective pixel and the pixel PX2 is a normal pixel. In the defective pixel repairing step, first, a laser LS is irradiated to the overlapping portion of the wirings 26a, 26b to short-circuit the wirings 26a, 26b (FIG. 5(a)). With this, the anode electrode of the organic EL element 24 in the defective pixel PX1 and the anode electrode of the organic EL element 24 in the normal pixel PX2 are electrically connected. Next, in the defective pixel PX1, the TFT 21 is electrically disconnected from the organic EL element 24 (FIG. 5(b)). Concretely, the source terminal of the TFT 21 in the defective pixel PX1 is electrically disconnected from the anode electrode of the organic EL element 24.

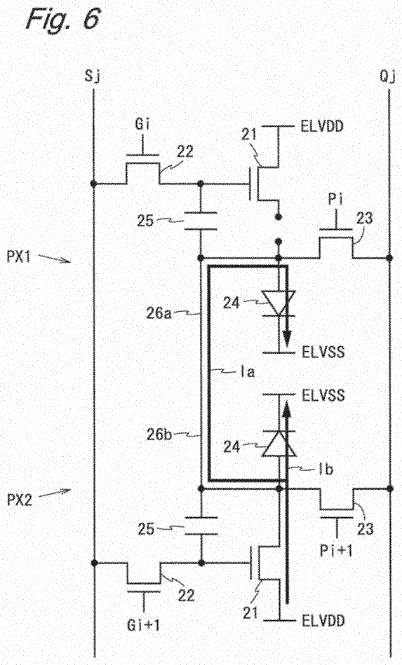

FIG. 6 is a circuit diagram of the pixels PX1, PX2 after repairing. In the pixels PX1, PX2 before repairing, a current through the TFT 21 and the organic EL element 24 flows from a power supply node having the high-level power supply voltage ELVDD to a power supply node having the low-level power supply voltage ELVSS. In the pixels PX1, PX2 after repairing, from the former power supply node to the latter power supply node, there flow a current Ia through the TFT 21 in the pixel PX2, the wiring 26b, the wiring 26a, and the organic EL element 24 in the pixel PX1, and a current Ib through the TFT 21 in the pixel PX2 and the organic EL element 24 in the pixel PX2. When characteristics of the organic EL element 24 are the same between the pixels 20, an amount of the current Ia and an amount of the current Ib become almost the same.

It is assumed that the above-described currents Ia, Ib are currents that flow through the organic EL element 24 in the pixels PX1, PX2 when a data voltage in accordance with a certain gradation G is written to the pixel PX2 after repairing. At this time, a current Iq that is a mixture of the currents Ia, Ib flows through the TFT 21 in the pixel PX2. It is assumed that Ip denotes a current flowing through the TFT 21 in the pixel PX2 when the data voltage in accordance with the same gradation G is written to the pixel PX2 before repairing. The current Ip is a current in a case where the anode electrode of the organic EL element 24 in the pixel PX1 and the anode electrode of the organic EL element 24 in the pixel PX2 are not electrically connected. The scanning line drive circuit 13 and the data line drive circuit 14 write, to the normal pixel PX2, a data voltage with which an amount of the current Iq is not less than one time and not more than two times an amount of the current Ip.

Generally, luminance of an organic EL element is proportional to an amount of a current flowing through the organic EL element. Furthermore, when the amount of the current Iq is k times the amount of the current Ip, the amounts of the currents Ia, Ib are almost k/2 times the amount of the current Ip. Therefore, luminance of the pixels PX1, PX2 after repairing (luminance of the organic EL elements 24 in the pixels PX1, PX2 after repairing) is almost k/2 times (not less than half and not more than one time) luminance of the pixel PX2 before repairing (luminance of the organic EL element 24 in the pixel PX2 before repairing).

In this manner, when the pixel PX1 is a defective pixel and the pixel PX2 is a normal pixel, by irradiating the laser to the overlapping portion of the two wirings 26a, 26b and electrically disconnecting, in the defective pixel PX1, the TFT 21 from the organic EL element 24, luminance of the defective pixel PX1 becomes almost the same as luminance of the normal pixel PX2 that shares the drive transistor. Therefore, according to the defective pixel repairing method according to the present embodiment, the defective pixel can be repaired easily.

As described above, the defective pixel repairing method according to the present embodiment is performed with respect to a display device (organic EL display device 10) having the plurality of pixels 20 each including a drive transistor (TFT 21) and an electro-optical element (organic EL element 24), and includes electrically connecting an anode electrode of the electro-optical element in a defective pixel (pixel PX1) with the anode electrode of the electro-optical element in an adjacent normal pixel (pixel PX2) of same color, by irradiating the laser LS to the overlapping portion of the two wirings 26a, 26b formed in the different wiring layers and having the overlapping portion via the insulating film in the plan view, to short-circuit the two wirings 26a, 26b (FIG. 5(a)), and electrically disconnecting, in the defective pixel, the drive transistor from the electro-optical element (FIG. 5(b)).

According to the defective pixel repairing method according to the present embodiment, by electrically connecting the anode electrode of the electro-optical element in the defective pixel with the anode electrode of the electro-optical element in the normal pixel and electrically disconnecting, in the defective pixel, the drive transistor from the electro-optical element, an amount of a current flowing through the electro-optical element in the defective pixel becomes almost the same as an amount of a current flowing through the electro-optical element in the normal pixel that shares the drive transistor, and luminance of the defective pixel becomes almost the same as luminance of the normal pixel that shares the drive transistor. Furthermore, the luminance of the defective pixel becomes as described above only by irradiating the laser to the overlapping portion of the two wirings and electrically disconnecting the drive transistor from the electro-optical element. Therefore, the defective pixel can be repaired easily.

The pixel 20 includes the connection wiring (wiring 26) having one end connected to the anode electrode of the electro-optical element, and the connection wiring in the pixel 20 and the connection wiring in an adjacent pixel are formed in the different wiring layers and have the overlapping portion via the insulating film in the plan view. In connecting, the laser LS is irradiated to the overlapping portion of the connection wiring (wiring 26a) in the defective pixel and the connection wiring (wiring 26b) in the adjacent normal pixel. One conduction terminal of the drive transistor (source terminal of TFT 21) is electrically connected to the anode electrode of the electro-optical element. In disconnecting, in the defective pixel, the one conduction terminal of the drive transistor is electrically disconnected from the anode electrode of the electro-optical element. When the adjacent pixel is a pixel of same color, layout of the pixel including the connection wiring can be performed easily by configuring the pixel and the adjacent pixel so as to have almost line-symmetric configurations.

The display device (organic EL display device 10) according to the present embodiment includes the plurality of scanning lines G1 to Gm, the plurality of data lines S1 to Sn, and the plurality of pixels 20 each including the drive transistor (TFT 21) and the electro-optical element (organic EL element 24). In the display device, the connection wiring (wiring 26) in the pixel 20 and the connection wiring in the adjacent pixel of same color are formed in the different wiring layers and have the overlapping portion via the insulating film in the plan view. Therefore, the defective pixel can be repaired easily.

The defective pixel (pixel PX1) is corresponded to the adjacent normal pixel (pixel PX2) of same color, the connection wiring (wiring 26a) in the defective pixel and the connection wiring (wiring 26b) in the normal pixel are short-circuited at the overlapping portion so that the anode electrode of the electro-optical element in the defective pixel and the anode electrode of the electro-optical element in the normal pixel are electrically connected, and in the defective pixel, the drive transistor is electrically disconnected from the electro-optical element. In the defective pixel, the one conduction terminal of the drive transistor is electrically disconnected from the anode electrode of the electro-optical element, and in the normal pixel, the one conduction terminal of the drive transistor is electrically connected to the anode electrode of the electro-optical element. Therefore, a display device in which the defective pixel is repaired easily can be configured.

The display device includes a drive circuit (scanning line drive circuit 13 and data line drive circuit 14) that drives the scanning lines G1 to Gm and the data lines S1 to Sn, and the drive circuit writes, to the normal pixel, a voltage with which an amount of a current (current Iq) flowing through the drive transistor in the normal pixel is not less than one time and not more than two times an amount of a current (current Ip) in a case where the anode electrode of the electro-optical element in the defective pixel and the anode electrode of the electro-optical element in the normal pixel are not electrically connected. With this, luminance of the defective pixel and luminance of the normal pixel can be set to almost not less than half and not more than one time the luminance of the normal pixel before repairing.

The above-described defective pixel repairing method can be performed not only with respect to the organic EL display device including the pixel having the configuration shown in FIG. 2, but also with respect to an organic EL display device having a plurality of pixels each including a drive transistor and an organic EL element. An overall configuration of the organic EL display device may be arbitrary, and a configuration of the pixel may be arbitrary as long as it includes the drive transistor and the organic EL element. Therefore, in the embodiments described below, description of the overall configuration of the organic EL display device and the configuration of pixel is omitted, and a layout of the connection wiring and a defective pixel repairing method are described.

### Second Embodiment

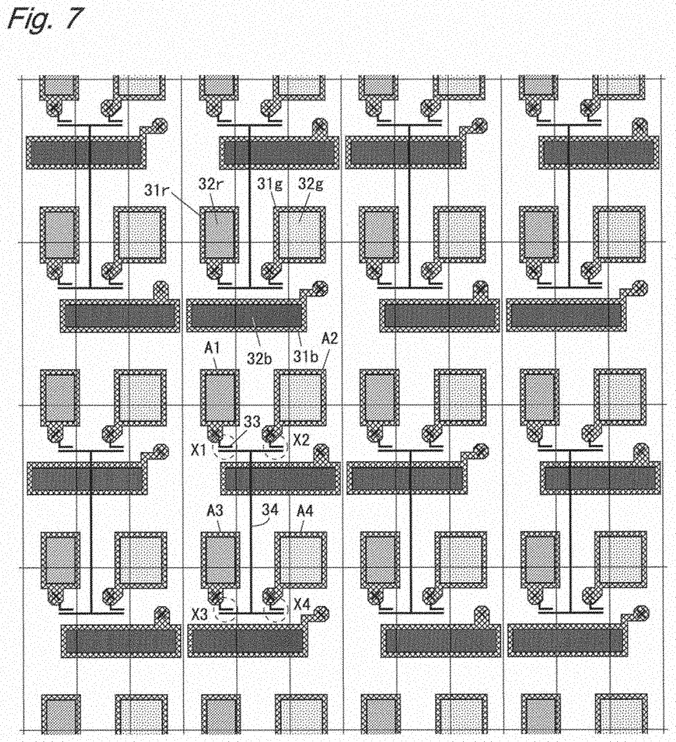

In a second embodiment, there describes a defective pixel repairing method of an organic EL display device having a display section of an S stripe arrangement. FIGS. 7 to 9 are layout diagrams of display sections of organic EL display devices according to first to third examples of the present embodiment, respectively. The layout diagrams shown below only describe elements necessary for understanding features of the defective pixel repairing methods. When two wirings are formed in different wiring layers and overlap via an insulating film in a plan view, the two wirings are described in parallel with a narrow interval.

In FIG. 7, an element with a reference character 31 represents an anode electrode of an organic EL element, and an element with a reference character 32 represents a light emitting area of the organic EL element. Red light emitting areas 32r and green light emitting areas 32g are arranged alternately side by side in the row direction. Blue light emitting areas 32b are arranged in a downward direction of the red light emitting areas 32r and the green light emitting areas 32g in the drawing. Anode electrodes 31r, 31g, 31b are formed so as to surround the light emitting areas 32r, 32g, 32b, respectively. In the display section shown in FIG. 7, a red pixel including the red light emitting area 32r is adjacent to four surrounding red pixels when paying an attention only to the red pixels. The same holds true for a green pixel including the green light emitting area 32g.

As a pixel group including two or more pixels for each of different colors, consider a pixel group including two red pixels arranged in a same column and two green pixels arranged in a same column. In the display section shown in FIG. 7, each pixel includes a wiring 33 having one end connected to the anode electrode 31, in addition to a drive transistor (not shown) and an organic EL element (not shown). The display section shown in FIG. 7 has an electrically isolated wiring 34 provided corresponding to the pixel group. The wiring 34 is formed in a wiring layer different from those of the anode electrode 31 and the wiring 33.

In FIG. 7, the anode electrodes with reference characters A1 to A4 are respectively referred to as first to fourth anode electrodes, and the pixels including the first to fourth anode electrodes are respectively referred to as first to fourth pixels. The wiring 34 has a first portion and a second portion extending in the row direction, and a third portion extending in the column direction. The first portion has an overlapping portion with the wiring 33 connected to the first anode electrode via the insulating film (not shown) in the plan view, and an overlapping portion with the wiring 33 connected to the second anode electrode via the insulating film in the plan view. The second portion has an overlapping portion with the wiring 33 connected to the third anode electrode via the insulating film via the insulating film in the plan view, and an overlapping portion with the wiring 33 connected to the fourth anode electrode via the insulating film in the plan view. The third portion connects the first portion and the second portion, and has an overlapping portion with the anode electrode 31b via the insulating film in the plan view. In this manner, the wiring 34 is formed in a wiring layer different from that of the wiring 33, and has an overlapping portion with the wiring 33 via the insulating film in the plan view with respect to each pixel in the pixel group. Furthermore, the wiring 34 has an overlapping portion with the anode electrode 31b of the organic EL element in the blue pixel via the insulating film.

Also with respect to the organic EL display device according to the first example, a detection step of the defective pixel and a repairing step thereof are performed after forming the display section and before shipping. When the defective pixel is the first pixel, a laser is irradiated to an overlapping portion X1 of the wiring 33 connected to the first anode electrode and the wiring 34, and an overlapping portion X3 of the wiring 33 connected to the third anode electrode and the wiring 34. With this, the first anode electrode and the third anode electrode are electrically connected. In addition to this, in the first pixel, the drive transistor (not shown) is electrically disconnected from the organic EL element.

When the defective pixel is the second pixel, the laser is irradiated to an overlapping portion X2 of the wiring 33 connected to the second anode electrode and the wiring 34, and an overlapping portion X4 of the wiring 33 connected to the fourth anode electrode and the wiring 34. With this, the second anode electrode and the fourth anode electrode are electrically connected. In addition to this, in the second pixel, the drive transistor (not shown) is electrically disconnected from the organic EL element. Similar processing is performed when the defective pixel is the third pixel or the fourth pixel.

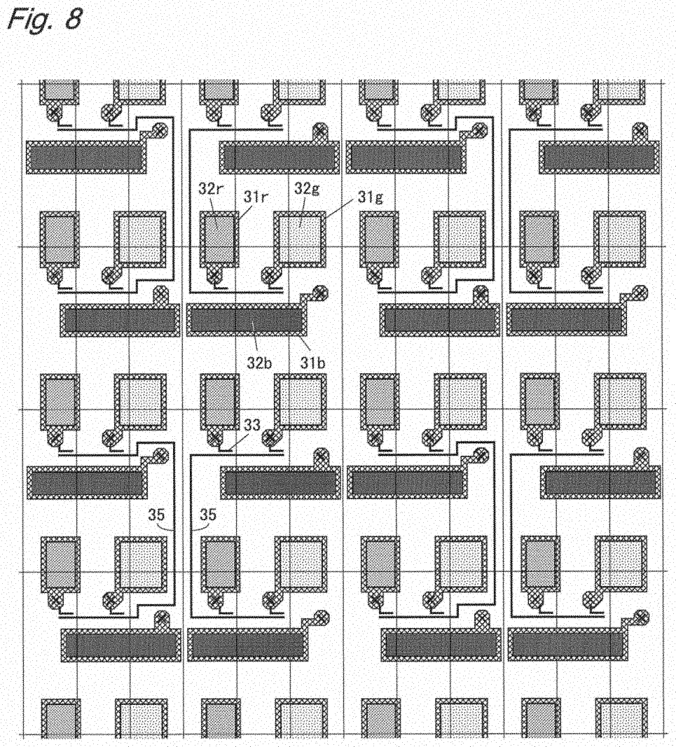

The display section shown in FIG. 8 has a wiring 35 in place of the wiring 34. The wiring 35 is formed in a wiring layer that is the same as that of the anode electrode 31 and is different from that of the wiring 33. As with the wiring 34, the wiring 35 has the first to third portions. However, the third portion of the wiring 35 does not overlap with the anode electrode 31b in the plan view. In this manner, the wiring 35 is formed so as not to overlap with the anode electrode 31b of the organic EL element in the blue pixel. The organic EL display device according to the second example is the same as the organic EL display device according to the first example except for the above-described point. The same defective pixel repairing process as that performed with respect to the organic EL display device according to the first example is performed with respect to the organic EL display device according to the second example.

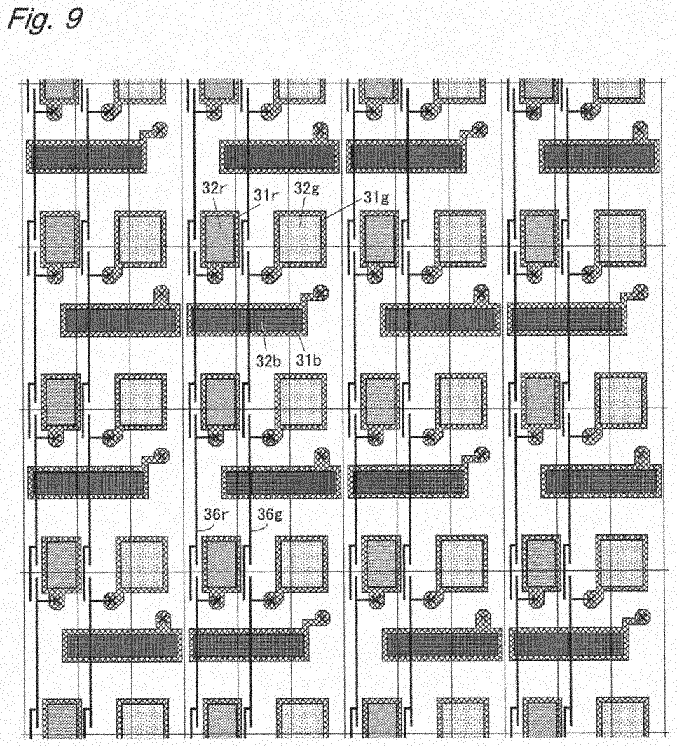

The display section shown in FIG. 9 has wirings 36r, 36g in place of the wirings 33, 34. The wiring 36r is provided for electrically connecting the anode electrodes 31r in the red pixels adjacent in the column direction. The wiring 36g is provided for electrically connecting the anode electrodes 31g in the green pixels adjacent in the column direction. However, when the connection wiring is provided for each color in this manner, a wiring area becomes large.

On the other hand, in the organic EL display devices according to the first example and the second example of the present embodiment, the wiring 34 or 35 is provided as a connection wiring common to the red pixels and the green pixels. Therefore, the wiring area can be reduced. Furthermore, since routing of the connection wiring is easy, the wiring 35 can be formed of a same material as the anode electrode 31 in an upmost layer, and the wirings 33, 35 can be connected using laser CVD (Chemical Vapor Deposition), as in the second example. With this, generation of particles due to a film skip that occurs when wirings in different layers are connected by irradiating the laser can be suppressed.

The defective pixel repairing methods according to the first and second examples of the present embodiment are performed with respect to a display device (organic EL display device) having a plurality of pixels each including a drive transistor and an electro-optical element (organic EL element). The pixel includes a first connection wiring (wiring 33) having one end connected to the anode electrode 31 of the electro-optical element. The display device includes an electrically isolated second connection wiring (wirings 34, 35) provided corresponding to a pixel group including two or more pixels for each of different colors (pixel group including two red pixels and two green pixels). The second connection wiring is formed in a wiring layer different from that of the first connection wiring, and has an overlapping portion (overlapping portions X1 to X4) with the first connection wiring via the insulating film in the plan view with respect to each pixel in the pixel group. In connecting, the laser is irradiated to the overlapping portion of the first connection wiring in the defective pixel and the second connection wiring, and the overlapping portion of one connection wiring in the normal pixel and the second connection wiring (for example, overlapping portions X1, X3). The wiring area can be reduced by using the second connection wiring common to the pixels of a plurality of colors.

A defective pixel is corresponded to a normal pixel of same color included in the same pixel group. The first connection wiring in the defective pixel and the second connection wiring are short-circuited at the overlapping portion and the first connection wiring in the normal pixel and the second connection wiring are short-circuited at the overlapping portion so that the anode electrode of the electro-optical element in the defective pixel and the anode electrode of the electro-optical element in the normal pixel are electrically connected, and in the defective pixel, the drive transistor is electrically disconnected from the electro-optical element. In the defective pixel, one conduction terminal of the drive transistor is electrically disconnected from the anode electrode of the electro-optical element, and in the normal pixel, the one conduction terminal of the drive transistor is electrically connected to the anode electrode of the electro-optical element.

The pixel group includes two or more first color pixels (two red pixels) arranged in a same column and two or more second color pixels (two green pixels) arranged in a same column, and the second connection wiring has an overlapping portion with the first connection wiring via the insulating film in the plan view with respect to each of the first color pixels, and an overlapping portion with the first connection wiring via the insulating film in the plan view with respect to each of the second color pixels. A plurality of pixels included in the pixel group commonly uses the second connection wiring.

In the display device according to the first example, the second connection wiring (wiring 34) has the overlapping portion with the anode electrode 31b of the electro-optical element in the blue pixel via the insulating film in the plan view. In the display device according to the second example, the second connection wiring (wiring 35) is formed so as not to overlap with the anode electrode 31b of the electro-optical element in the blue pixel in the plan view.

### Third Embodiment

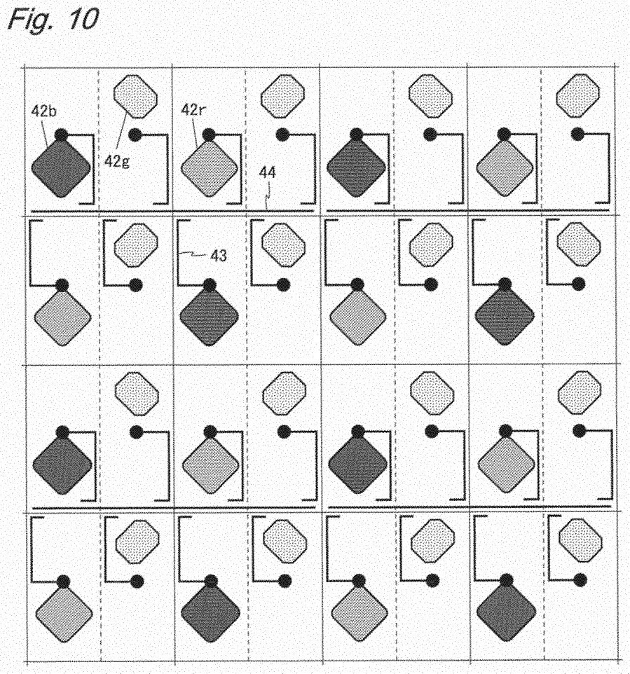

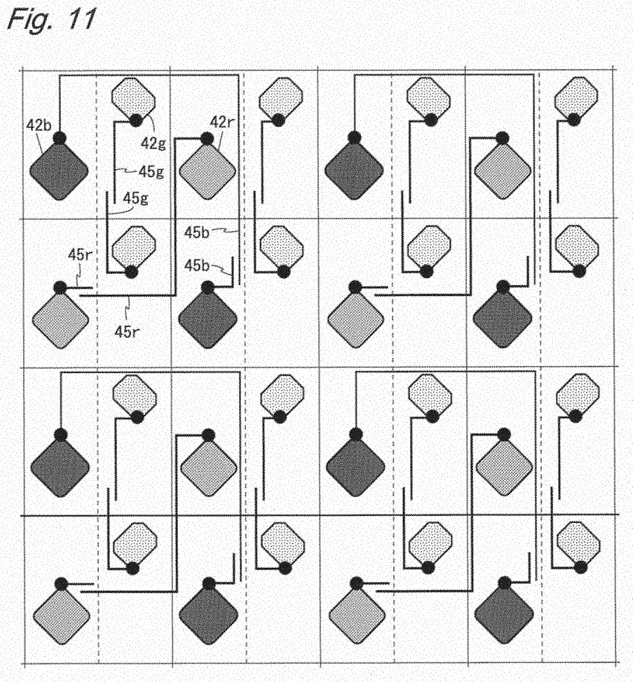

In a third embodiment, there describes a defective pixel repairing method of an organic EL display device having a display section using a diamond pen tile array. FIGS. 10 and 11 are layout diagrams of display sections of the organic EL display device according to first and second examples of the present embodiment, respectively. In FIG. 10, an element with a reference character 42 represents a light emitting area of the organic EL element. Note that the anode electrode of the organic EL element is omitted in the layout diagrams shown below. The anode electrode of the organic EL element is formed so as to include the light emitting area and a black circle in the drawings.

Green light emitting areas 42g are arranged side by side in the row direction and in the column direction. Red light emitting areas 42r and blue light emitting areas 42b are alternately arranged near centers of (2×2) green emitting areas 42g. As a pixel group including two or more pixels for each of different colors, consider a pixel group including two red pixels, four green pixels, and two blue pixels. In the display section shown in FIG. 10, each pixel includes a wiring 43 having one end connected to the anode electrode (not shown) of the organic EL element. The wiring 43 has a same shape. The display section shown in FIG. 10 includes an electrically isolated wiring 44 provided corresponding to the pixel group. The wiring 44 is formed in a wiring layer different from those of the anode electrode of the organic EL element and the wiring 43. The wiring 44 extends in the row direction and has an overlapping portion with the wiring 43 via the insulating film in the plan view with respect to each pixel in the pixel group.

Also with respect to the organic EL display device according to the present embodiment, a detecting step of the defective pixel and a repairing step thereof are performed after forming the display section and before shipping. When the defective pixel is the red pixel, the laser is irradiated to the overlapping portion of the wiring 43 connected to the anode electrode of the organic EL element in the defective red pixel and the wiring 44, and the overlapping portion of the wiring 43 connected to the anode electrode of the organic EL element in a normal red pixel and the wiring 44. With this, the anode electrode of the organic EL element in the defective red pixel and the anode electrode of the normal organic EL element in the normal red pixel are electrically connected. Furthermore, in the defective red pixel, the drive transistor (not shown) is electrically disconnected from the organic EL element. Similar processing is performed when the defective pixel is the green pixel or the blue pixel.

In the display section shown in FIG. 11, each pixel includes a wiring 45 having one end connected to the anode electrode (not shown) of the organic EL element. A wiring 45r is provided for electrically connecting the anode electrodes (not shown) of the organic EL elements in two red pixels. A wiring 45g is provided for electrically connecting the anode electrodes (not shown) of the organic EL elements in two green pixels. A wiring 45b is provided for electrically connecting the anode electrodes (not shown) of the organic EL elements in two blue pixels. However, when the connection wiring is provided for each color in this manner, the wiring area becomes large.

On the other hand, in the organic EL display device according to the first example of the present embodiment, the wiring 44 is provided as a second connection wiring common to the red pixels, the green pixels, and the blue pixels. Therefore, the wiring area can be reduced. Furthermore, the first connection wiring (wiring 43) has a same shape. Therefore, layout of the display section including the wiring 43 can be performed easily. In addition to this, since load capacitances become the same among the pixels of same color, pull-in voltages due to the load capacitances become the same among the pixels of the same color. Therefore, a deviation of a drive voltage of the organic EL element can be suppressed.

Note that although in the first to third embodiments, an organic EL display device having a pixel including an organic EL element (organic light emitting diode) is described as an example of a display device having a pixel including a drive transistor and an electro-optical element, an inorganic EL display device having a pixel including an inorganic light emitting diode or a QLED (Quantum-dot Light Emitting Diode) display device having a pixel including a quantum dot light emitting diode may be configured by a similar method.

In the above-described defective pixel repairing methods, in electrically connecting the anode electrodes of the electro-optical elements, two wiring are short-circuited by irradiating the laser to the overlapping portion of the two wirings formed in the different wiring layers and having the overlapping portion via the insulating film in the plan view. In place of this, without providing any wiring in advance, in electrically connecting the anode electrodes of the electro-optical elements, a wiring electrically connecting the anode electrode of the electro-optical element in the defective pixel with the anode electrode of the electro-optical element in the normal pixel of same color may be newly formed by laser CVD using a material such as tungsten.

### DESCRIPTION OF REFERENCE CHARACTERS

10: ORGANIC EL DISPLAY DEVICE
11: DISPLAY SECTION
12: DISPLAY CONTROL CIRCUIT
13: SCANNING LINE DRIVE CIRCUIT
14: DATA LINE DRIVE CIRCUIT
20: PIXEL
21 to 23: TFT
24: ORGANIC EL ELEMENT
25: CAPACITOR
26, 33 to 36, 43 to 45: WIRING
31: ANODE ELECTRODE
32, 42: LIGHT EMITTING AREA
LS: LASER

1. A defective pixel repairing method of a display device having a plurality of pixels each including a drive transistor and an electro-optical element, the method comprising:
electrically connecting an anode electrode of the electro-optical element in a defective pixel with the anode electrode of the electro-optical element in an adjacent normal pixel of same color, by irradiating a laser to an overlapping portion of two wirings formed in different wiring layers and having the overlapping portion via an insulating film in a plan view, to short-circuit the two wirings; and
electrically disconnecting, in the defective pixel, the drive transistor from the electro-optical element.

2. The defective pixel repairing method according to claim 1, wherein
the pixel further includes a connection wiring having one end connected to the anode electrode of the electro-optical element,
the connection wiring in the pixel and the connection wiring in an adjacent pixel of same color are formed in the different wiring layers and have the overlapping portion via the insulating film in the plan view, and
in connecting, the laser is irradiated to the overlapping portion of the connection wiring in the defective pixel and the connection wiring in the normal pixel.

3. The defective pixel repairing method according to claim 1, wherein
the pixel further includes a first connection wiring having one end connected to the anode electrode of the electro-optical element,
the display device further has an electrically isolated second connection wiring provided corresponding to a pixel group including two or more pixels for each of different colors,
the second connection wiring is formed in a wiring layer different from a wiring layer of the first connection wiring, and has the overlapping portion with the first connection wiring via the insulating film in the plan view with respect to each pixel in the pixel group, and
in connecting, the laser is irradiated to the overlapping portion of the first connection wiring in the defective pixel and the second connection wiring, and the overlapping portion of the first connection wiring in the normal pixel and the second connection wiring.

4. The defective pixel repairing method according to claim 1, wherein
one conduction terminal of the drive transistor is electrically connected to the anode electrode of the electro-optical element, and
in disconnecting, in the defective pixel, the one conduction terminal of the drive transistor is electrically disconnected from the anode electrode of the electro-optical element.

5. The defective pixel repairing method according to claim 3, wherein
the pixel group includes two or more first color pixels arranged in a same column and two or more second color pixels arranged in a same column, and
the second connection wiring has the overlapping portion with the first connection wiring via the insulating film in the plan view with respect to each of the first color pixels, and has the overlapping portion with the first connection wiring via the insulating film in the plan view with respect to each of the second color pixels.

6. The defective pixel repairing method according to claim 3, wherein a plurality of pixels included in the pixel group commonly uses the second connection wiring.

7. The defective pixel repairing method according to claim 3, wherein the pixel group includes two red pixels and two green pixels.

8. The defective pixel repairing method according to claim 7, wherein the second connection wiring has an overlapping portion with the anode electrode of the electro-optical element in a blue pixel via the insulating film in the plan view.

9. The defective pixel repairing method according to claim 7, wherein the second connection wiring is formed so as not to overlap with the anode electrode of the electro-optical element in a blue pixel in the plan view.

10. The defective pixel repairing method according to claim 3, wherein the pixel group includes two red pixels, four green pixels, and two blue pixels.

11. The defective pixel repairing method according to claim 3, wherein the first connection wiring has a same shape.

12. A display device comprising:
a plurality of scanning lines;
a plurality of data lines; and
a plurality of pixels each including a drive transistor, an electro-optical element, and a connection wiring having one end connected to an anode electrode of the electro-optical element, wherein
the connection wiring in the pixel and the connection wiring in an adjacent pixel of same color are formed in different wiring layers and have an overlapping portion via an insulating film in a plan view.

13. The display device according to claim 12, wherein
a defective pixel is corresponded to an adjacent normal pixel of same color,
the connection wiring in the defective pixel and the connection wiring in the normal pixel are short-circuited at the overlapping portion so that the anode electrode of the electro-optical element in the defective pixel and the anode electrode of the electro-optical element in the normal pixel are electrically connected, and
in the defective pixel, the drive transistor is electrically disconnected from the electro-optical element.

14. A display device comprising:
a plurality of scanning lines;
a plurality of data lines;
a plurality of pixels each including a drive transistor, an electro-optical element, and a first connection wiring having one end connected to an anode electrode of the electro-optical element; and
an electrically isolated second connection wiring provided corresponding to a pixel group including two or more pixels for each of different colors, wherein
the second connection wiring is formed in a wiring layer different from a wiring layer of the first connection wiring, and has an overlapping portion with the first connection wiring via an insulating film in a plan view with respect to each pixel in the pixel group.

15. The display device according to claim 14, wherein
a defective pixel is corresponded to a normal pixel of same color included in a same pixel group,
the first connection wiring in the defective pixel and the second connection wiring are short-circuited at the overlapping portion and the first connection wiring in the normal pixel and the second connection wiring are short-circuited at the overlapping portion so that the anode electrode of the electro-optical element in the defective pixel and the anode electrode of the electro-optical element in the normal pixel are electrically connected, and
in the defective pixel, the drive transistor is electrically disconnected from the electro-optical element.

16. The display device according to claim 13, wherein
in the defective pixel, one conduction terminal of the drive transistor is electrically disconnected from the anode electrode of the electro-optical element, and
in the normal pixel, the one conduction terminal of the drive transistor is electrically connected to the anode electrode of the electro-optical element.

17. The display device according to claim 13 or 15, further comprising a drive circuit configured to drive the scanning lines and the data lines, wherein
the drive circuit writes, to the normal pixel, a voltage with which an amount of a current flowing through the drive transistor in the normal pixel is not less than one time and not more than two times an amount of a current in a case where the anode electrode of the electro-optical element in the defective pixel and the anode electrode of the electro-optical element in the normal pixel are not electrically connected.

18. The display device according to claim 14, wherein
the pixel group includes two or more first color pixels arranged in a same column and two or more second color pixels arranged in a same column, and
the second connection wiring has the overlapping portion with the first connection wiring via the insulating film in the plan view with respect to each of the first color pixels, and has the overlapping portion with the first connection wiring via the insulating film in the plan view with respect to each of the second color pixels.

19. The display device according to claim 14, wherein a plurality of pixels included in the pixel group commonly uses the second connection wiring.

20. The display device according to claim 14, wherein the pixel group includes two red pixels and two green pixels.

21-24. (canceled)
